(19) United States
(12) Patent Application Publication
(10) Pub. No.: US 2013/0156530 A1
(43) Pub. Date: Jun. 20, 2013

(54) METHOD AND APPARATUS FOR REDUCING CONTAMINATION OF SUBSTRATE

(71) Applicants: Robert Sculac, Lake Oswego, OR (US); Aaron Francis, San Jose, CA (US); Satbir Kahlon, Livermore, CA (US); Le Marious Sword, Sunnyvale, CA (US)

(72) Inventors: Robert Sculac, Lake Oswego, OR (US); Aaron Francis, San Jose, CA (US); Satbir Kahlon, Livermore, CA (US); Le Marious Sword, Sunnyvale, CA (US)

(73) Assignee: Intermolecular, Inc., San Jose, CA (US)

(21) Appl. No.: 13/325,232

(22) Filed: Dec. 14, 2011

(51) Int. Cl. H01L 21/677; B25J 11/00; B23Q 1/25; B25J 15/00

(52) U.S. Cl. 414/222.13; 414/222.01; 269/55

(57) ABSTRACT

An aligner, chuck, and end effector for substrate processing are provided. The aligner includes a rotatable substrate support having a surface for supporting the substrate. The rotatable substrate support has a diameter less than a diameter of the substrate and surfaces of the rotatable substrate support are coated with a coating consisting essentially of a poly(p-xylylene) polymer. The chuck includes a flat platform that supports the substrate during processing. The chuck is larger than the substrate and may include holes though which lift pins can pass assist the loading/unloading of the substrate. The end effector includes an arm supporting a first extension and a second extension, wherein the arm, the first extension and the second extension are coated with a coating consisting essentially of a poly(p-xylylene) polymer.

### BACKGROUND

Combinatorial processing enables rapid evaluation of semiconductor processes. The systems supporting the combinatorial processing are flexible to accommodate the demands for running the different processes either in parallel, serial or some combination of the two.

Some exemplary semiconductor wet processing operations include operations for adding (electro-depositions) and removing layers (etch), defining features, preparing layers (e.g., cleans), etc. Similar processing techniques apply to the manufacture of integrated circuits (IC) semiconductor devices, flat panel displays, optoelectronics devices, data storage devices, magneto electronic devices, magneto optic devices, packaged devices, and the like. As feature sizes continue to shrink, improvements, whether in materials, unit processes, or process sequences, are continually being sought for the deposition processes. However, semiconductor companies conduct R&D on full wafer processing through the use of split lots, as the deposition systems are designed to support this processing scheme. This approach has resulted in ever escalating R&D costs and the inability to conduct extensive experimentation in a timely and cost effective manner. Combinatorial processing as applied to semiconductor manufacturing operations enables multiple experiments to be performed on a single substrate.

During combinatorial experiments it is beneficial to provide as much flexibility as possible with regard to the tools performing the processing. In addition, the equipment for performing the combinatorial experiments should be designed to minimize particle generation and be able to withstand a corrosive processing environment. It is within this context that the embodiments arise.

### SUMMARY

Embodiments of the present invention provide an apparatus that minimizes particle generation caused by equipment when processing a semiconductor substrate. Several inventive embodiments of the present invention are described below.

In some embodiments of the invention an aligner for substrate processing is provided. The aligner includes a rotatable substrate support having a surface for supporting the substrate. The rotatable substrate support has a diameter less than a diameter of the substrate and surfaces of the rotatable substrate support are coated with a coating consisting essentially of a poly(p-xylylene) polymer.

In some embodiments of the invention, an end effector is provided. The end effector includes an arm supporting a first extension and a second extension, wherein the arm, the first extension and the second extension are coated with a coating consisting essentially of a poly(p-xylylene) polymer.

Other aspects of the invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings, and like reference numerals designate like structural elements.

FIG. 1 illustrates a schematic diagram for implementing combinatorial processing and evaluation using primary, secondary, and tertiary screening.

FIG. 2 is a simplified schematic diagram illustrating a general methodology for combinatorial process sequence integration that includes site isolated processing and/or conventional processing in accordance with some embodiments of the invention.

FIG. 3A is a simplified schematic diagram of a combinatorial system which may incorporate wet processing experiments or semiconductor manufacturing process sequences and unit operations in order to combinatorially evaluate various semiconductor manufacturing processes so that an optimum process may be found in a minimum amount of time in accordance with some embodiments of the invention.

FIG. 3B is a top view of a substrate having regions processed differently through the modular head system described herein in accordance some embodiments of the invention.

FIG. 4 is a cross sectional view of a combinatorial processing system in accordance with some embodiments of the invention.

FIG. 5 is a simplified schematic diagram illustrating a perspective view of an end effector in accordance with one embodiment of the invention.

FIG. 6 is a simplified schematic diagram illustrating a cross-sectional view of an aligner in accordance with one embodiment of the invention.

### DETAILED DESCRIPTION

The embodiments described herein provide a method and apparatus for a substrate processing system that minimizes unwanted contamination to a substrate during handling and processing operations. It will be obvious, however, to one skilled in the art, that the present invention may be practiced without some or all of these specific details. In other instances, well known process operations have not been described in detail in order not to unnecessarily obscure the present invention.

The embodiments describe an apparatus and method for protecting the surfaces of a substrate being processed through a conventional or combinatorial processing system, such as the Tempus F-30 system from the assignee, from metal and particle contamination in some embodiments. In order to provide further protection to the backside of the substrate from metal contamination, a coating is applied to the contact surfaces of components contacting the backside of the substrate. The contact surfaces are coated with poly(p-xylylene) polymers, also known as PARYLENE™. The embodiments below are directed toward the surfaces of the end effector utilized to transport the substrate and the aligner chuck utilized to align the substrate for processing. It should be appreciated that any other surfaces contacting the substrate may include the coating, such as a wafer pedestal or other substrate support for a processing tool, air bearings/air tracks, wafer cassettes, vacuum wands, and other suitable tools utilized to hold, support, or transport a wafer, along with hardware that is immersed in the chemistry or gas feed path, and hardware items that are in close proximity to the wafer surface such as showerheads and process chamber walls. The poly(p-xylylene) polymers are resistant to strong acids, i.e., corrosive environments. The coating enables higher component lifetime as pitting protection is provided for a longer period of time, especially from the corrosive environments the end effector may be exposed to. In some embodiments, metal contamination of the backside of the substrate is avoided when the tools contacting the substrate has the coating. It should be appreciated that use of the poly(p-xylylene) polymer coating on the end effector enables the same end effector/robot module to be used for front opening unified pod (FOUP) load/unload and wet processing module transport for combinatorial processing, as opposed to different end effectors due to the corrosive materials utilized by the processing tools. While the embodiments refer to combinatorial processing, it should be appreciated that the coating may be applied to tools utilized in conventional or other non-combinatorial processing.

Semiconductor manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD).

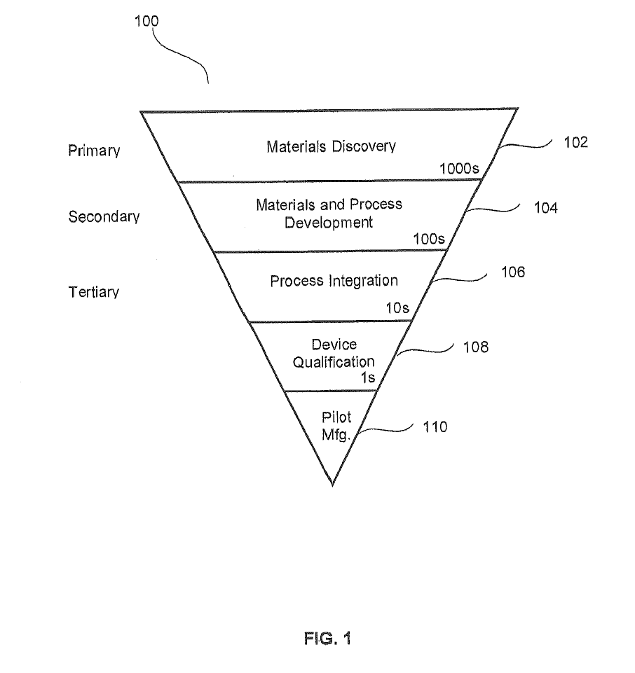

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

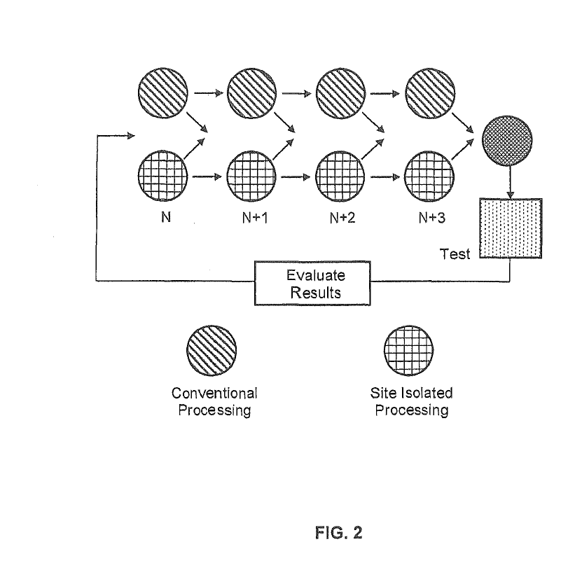

FIG. 2 is a simplified schematic diagram illustrating a general methodology for combinatorial process sequence integration that includes site isolated processing and/or conventional processing in accordance with some embodiments of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

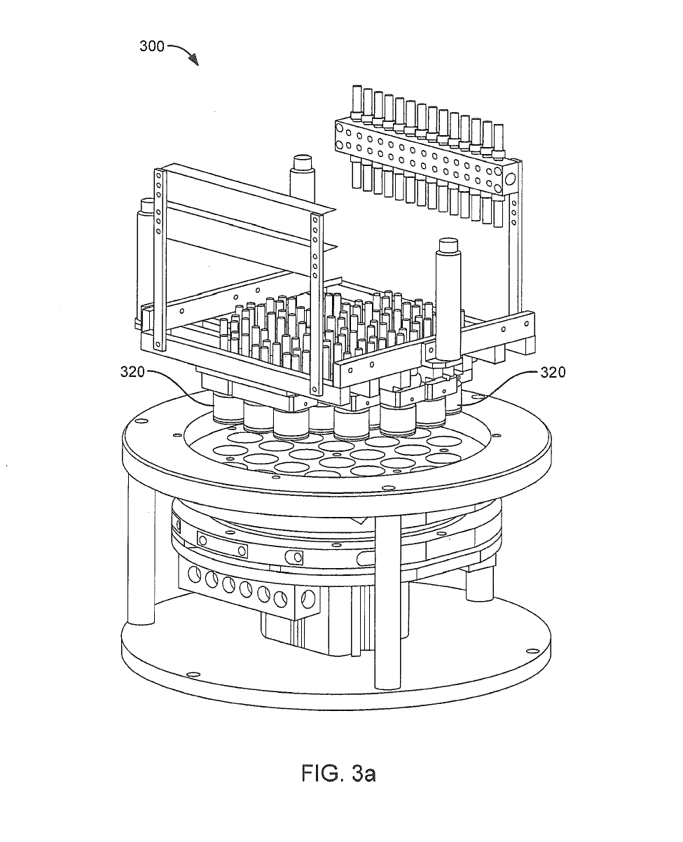

FIG. 3A is a simplified schematic diagram of a combinatorial system which may incorporate wet processing experiments or semiconductor manufacturing process sequences and unit operations in order to combinatorially evaluate various semiconductor manufacturing processes so that an optimum process may be found in a minimum amount of time in accordance with some embodiments of the invention. System 300 includes a plurality of flow cells 320 which may be modular in design as in order to efficiently evaluate a plurality of processes and utilize the same tool on various programs addressing customer specific problems and enabling the use of using customer specific wafers without requiring re-tooling. In one embodiment, twenty eight flow cells are provided for twenty eight discrete regions of a twelve inch wafer. It should be appreciated that this is not meant to be limiting as any number of flow cells 320 may be accommodated on a system depending on various factors including the size and shape of the substrate being evaluated, the size of the regions on the substrate, etc. It should be appreciated that a monolithic block design is or a modular design for the flow cell 320 may be integrated with the embodiments of the invention. In addition, a rail system enabling flow cells 320 to be tailored to any pitch (e.g., spacing) of regions is provided. A flexible reactor based system is provided in addition to a static manifold system. System 300 includes a plurality of connections (not shown for illustrative purposes) distributed to each of flow cells 320. One skilled in the art will appreciate that the system of FIG. 3A may be connected to various inputs that may be affixed to system 300 through racks or external to system 300. Exemplary inputs include a dispense manifold to dispense any process fluids utilized in the system, a mix vessel for optionally mixing fluids prior to delivery to system 300, and any required power and gas inputs to operate the system. In addition, a waste collection mechanism may be in communication to receive process fluids evacuated from the reaction chambers or bypassed through flow cells 320. It should be further appreciated that while flow cells 320 are depicted as each having a certain number of inputs and outputs, the number of inputs and outputs may be varied as the illustrations are exemplary. System 300 is configured to concurrently process different regions of the substrate differently. Further details on the flow cell configuration may be found in U.S. patent application Ser. No. 11/352,077 entitled “Methods for Discretized Processing and Process Sequence Integration of Regions of Substrate” filed on Feb. 10, 2006 and claiming priority to U.S. Provisional Application No. 60/725,186 filed on Oct. 11, 2005 and U.S. patent application Ser. No. 11/966,809 entitled “Vented Combinatorial Processing Cell” filed on Dec. 28, 2007, and claiming priority to U.S. Provisional Application No. 61/014,672 filed on Dec. 18, 2007, the entireties of which are hereby incorporated by reference.

FIG. 3B is a top view of a substrate having regions processed differently through the modular head system described herein in accordance with some embodiments of the invention. Substrate 340 has a plurality of regions 302, which have been combinatorially processed. Twenty eight regions are provided on substrate 340 in this exemplary embodiment. Substrate 340 is illustrated as having a substantially flat surface in this exemplary embodiment, although this is not meant to be limiting. More or fewer regions can be defined in alternative embodiments. It should be appreciated that on substrate 340 a wealth of knowledge exists on a single substrate as each of regions 302 may have some property or characteristic of the process altered. Thus, the information available for each region as well as the interaction of each region with previous or subsequent process operations or materials may be harvested to provide data on an optimum material, unit process and/or process sequence in a highly efficient manner. While FIG. 3B illustrates regions 302 as isolated and not overlapping, the regions may overlap in one embodiment. In another embodiment a region refers to a localized area on a substrate which is, was, or is intended to be used for processing or formation of a selected material. The region can include one region and/or a series of regular or periodic regions pre-formed on the substrate. The region may have any convenient shape, e.g., circular, rectangular, elliptical, wedge-shaped, etc. In one embodiment, regions 302 are predefined on the substrate. However, the processing may define the regions 302 in another embodiment.

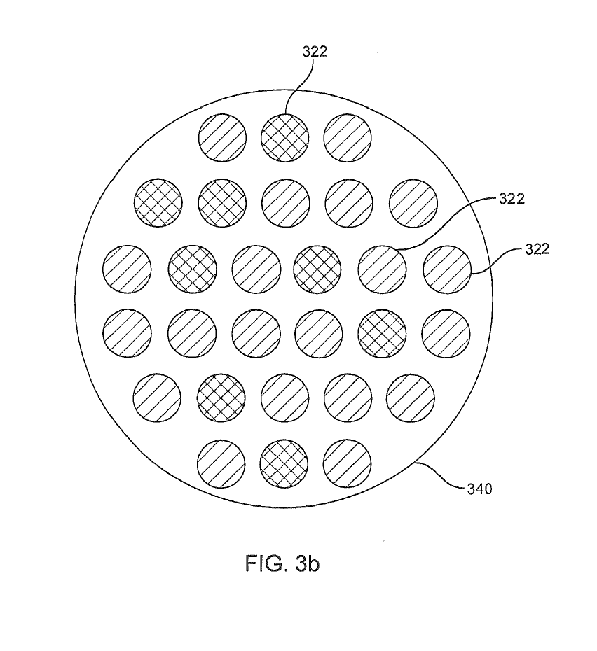

FIG. 4 is a cross sectional view of a combinatorial processing system in accordance with some embodiments of the invention. FIG. 4 illustrates system 400 that includes a reactor block 406 disposed over stage or chuck 402 which can secure substrate 340. Reactor block 406 defines an array of reactors 408, also referred to as reaction areas, that define a pattern of isolated reaction regions when sealed against a surface of substrate 340 for performing a process in each reaction region. System 400 includes a floating or removable reactor sleeve 410. Removable reactor sleeve 410 is configured to float or be dynamically positionable in each reactor 408 of the flow cell assembly block 406 in some embodiments. Flow cell 320 of FIG. 3A may be disposed into each of reactor 408 in some embodiments. Use of the removable sleeves 410 in each reactor 408 allows for replacement of individual reactor walls that may become contaminated or otherwise unsuitable for continued use in a reactor. Piston 404 provides the force to raise substrate support or chuck 402 so that a surface of substrate 340 is forced against sealing surfaces of removable sleeves 410 in some embodiments. In some embodiments, the exposed surfaces of chuck 402 is coated with poly(p-xylylene) polymers. Controller 412 monitors and controls the force of the substrate 340 against the sealing surfaces in some embodiments. Controller 412 may be a general purpose computer or a special purpose computer.

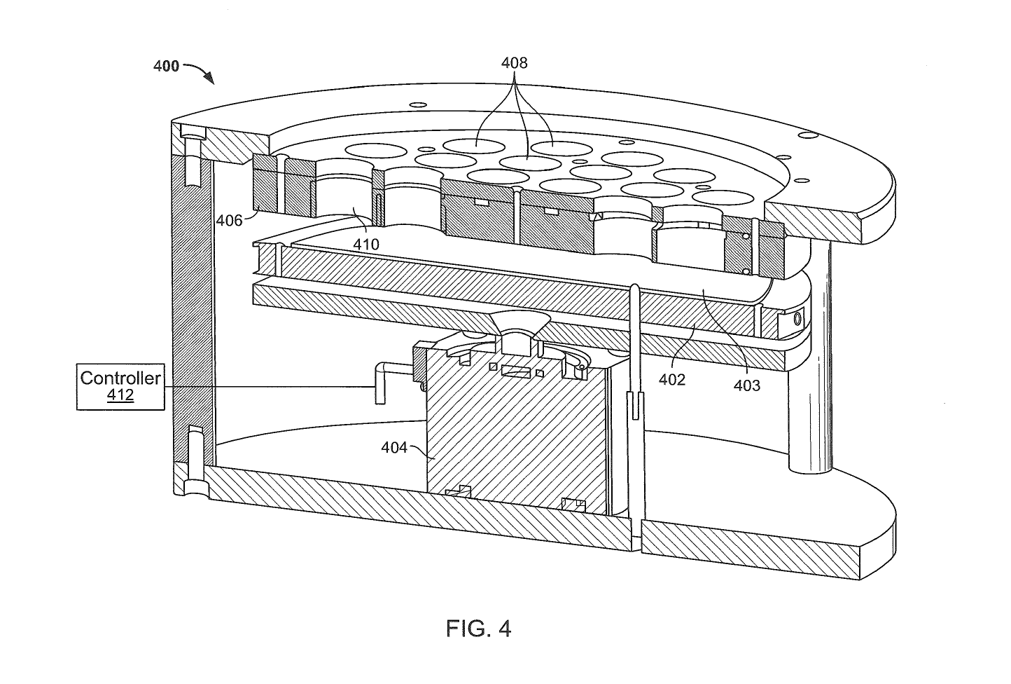

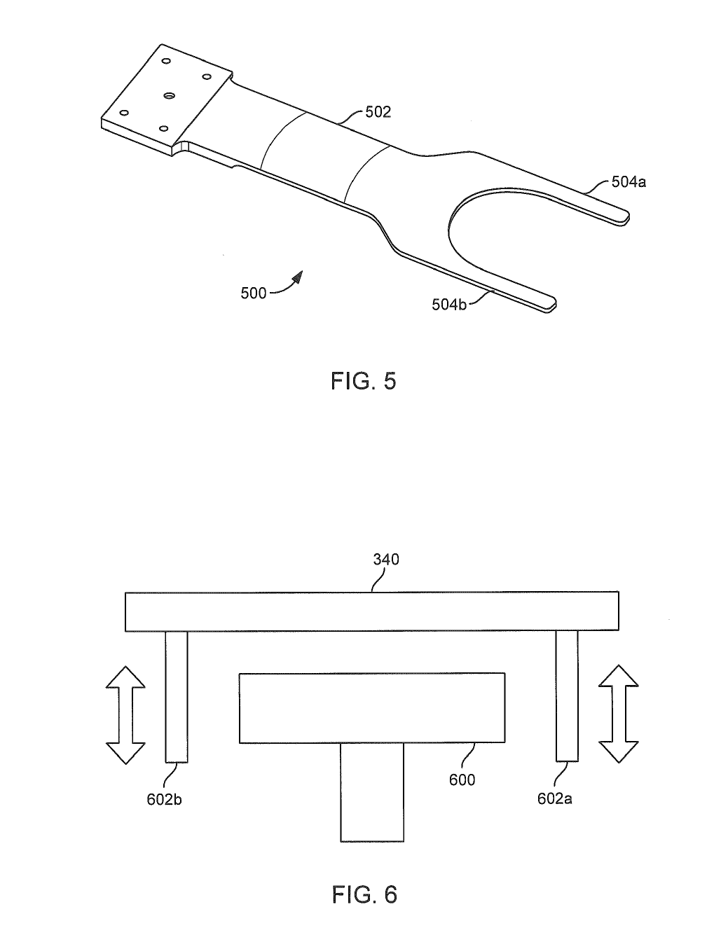

FIG. 5 is a simplified schematic diagram illustrating a perspective view of an end effector in accordance with one embodiment of the invention. End effector 500 includes arm 502 having extensions 504a and 504b extending therefrom. In accordance with some embodiments of the invention arm 502 and extensions 504a and 504b are coated with poly(p-xylylene) polymers. It should be appreciated that the configuration of end effector 500 is not meant to be limiting. That is, end effector 500 may come in various shapes and sizes where all the contact surfaces of the end effector or expose surfaces of the end effector are coated with poly(p-xylylene). The poly(p-xylylene) polymer coating on the end effector 500 enables the same end effector/robot module to be used for a FOUP load/unload and wet processing module, e.g., the module of FIG. 3A, as opposed to different end effectors. The use of a single end effector eliminates additional hand-offs and system complexity, as well as reducing the footprint of the tools required to perform the processing. The poly(p-xylylene) polymer coating on the end effector also increases the lifetime of the end effector, whether the end effector is a metal based end effector or a ceramic based end effector. The prevention of pitting of the surfaces of the coated end effector from the repeated exposure to the corrosive processing environment maintains acceptable levels of residual metal and particle levels over the lifetime of the end effector without the need for costly preventative maintenance. Although the end effector has been described and discussed in relation to a combinatorial processing system, those skilled in the art will understand that the end effector is also operable for use with any known conventional processing system. The use of the exemplary combinatorial processing system is not meant to be limiting. FIG. 6 is a simplified schematic diagram illustrating a cross-sectional view of an aligner in accordance with one embodiment of the invention. Aligner puck 600 is configured to support substrate 340. In some embodiments aligner puck 600 is configured to rotate around an axis of the aligner and move in a vertical direction. Aligner puck 600 may be referred to as a rotatable substrate support. It should be appreciated that aligner puck supports a portion of the substrate, i.e., the aligner puck has a diameter that is smaller than the diameter of substrate 340. Pins 602a and 602b are configured to accept substrate 340 from an end effector, such as the end effector of FIG. 5. Pins 602a and 602b are configured to move in a vertical direction in order to place substrate 340 onto a surface of aligner puck 600 and remove the substrate from the surface of the aligner puck. It should be appreciated that pins 602a and 602b are optional and the aligner may include the puck only in some embodiments. The aligner system may be incorporated into a processing system that includes the wet processing module of FIG. 3A and the spin rinse and dry (SRD) module where an end effector, such as the end effector of FIG. 5, transports the substrate between the modules. For the combinatorial processing, the aligner system may rotate the substrate so that a particular region is processed in a particular reactor and flow cell of the wet processing module in some embodiments. Additional details of the wet processing module of FIG. 3A and the SRD module may be found in U.S. patent application Ser. No. ______ entitled “Method and Apparatus for Dispensing an Inert Gas” filed on Nov. xx, 2011 and having Attorney Docket No. (IM0464_US), and is herein incorporated by reference. Although the aligner system has been described and discussed in relation to a combinatorial processing system, those skilled in the art will understand that the aligner system is also operable for use with any known conventional processing system. The use of the exemplary combinatorial processing system is not meant to be limiting.

Any of the operations described herein that form part of the invention are useful machine operations. The invention also relates to a device or an apparatus for performing these operations. The apparatus can be specially constructed for the required purpose, or the apparatus can be a general-purpose computer selectively activated or configured by a computer program stored in the computer. In particular, various general-purpose machines can be used with computer programs written in accordance with the teachings herein, or it may be more convenient to construct a more specialized apparatus to perform the required operations.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims. In the claims, elements and/or steps do not imply any particular order of operation, unless explicitly stated in the claims.

What is claimed is:

1. An aligner for semiconductor substrate processing, comprising:
a rotatable substrate support having a surface for supporting a semiconductor substrate, wherein the rotatable substrate support is coated with a coating consisting essentially of a poly(p-xylylene) polymer.

2. The aligner of claim 1, wherein the aligner is moveable in a vertical direction.

3. The aligner of claim 1, wherein the aligner is configured to receive the semiconductor substrate from an end effector, and wherein surfaces of the end effector contacting the substrate are coated with the coating consisting essentially of the poly(p-xylylene) polymer.

4. The aligner of claim 1, wherein the aligner includes a plurality of moveable pins disposed around an outer edge of the rotatable substrate support.

5. The aligner of claim 1, wherein each of the plurality of moveable pins is coated with the coating consisting essentially of the poly(p-xylylene) polymer.

6. The aligner of claim 1, wherein the aligner is integrated into a combinatorial processing system having a wet processing module, a spin rinse and dry module, and an end effector operable to transport the semiconductor substrate between the aligner, the wet processing module and the spin rinse and dry module.

7. The aligner of claim 6, wherein the wet processing module is configured to contemporaneously process different regions of the semiconductor substrate in a combinatorial manner.

8. The aligner of claim 1, wherein the aligner is integrated into a semiconductor processing tool having a plurality of processing modules, the semiconductor processing tool having an end effector operable to transport the semiconductor substrate between the plurality of processing modules.

9. An end effector for transporting a semiconductor substrate, comprising:
an arm supporting a first extension and a second extension, wherein the arm, the first extension, and the second extension are coated with a coating consisting essentially of a poly(p-xylylene) polymer.

10. The end effector of claim 9, wherein the end effector is composed of aluminum.

11. The end effector of claim 9, wherein the end effector is composed of a ceramic material.

12. The end effector of claim 9, wherein the end effector is integrated into a combinatorial processing system having a wet processing module, a spin rinse and dry module, and the end effector is operable to transport the semiconductor substrate between the aligner, the wet processing module, and the spin rinse and dry module.

13. The end effector of claim 12, wherein the semiconductor substrate has a plurality of regions, each of the plurality of regions processed in a combinatorial manner within the wet processing module.

14. The end effector of claim 9 wherein the end effector is integrated into a semiconductor processing tool having a plurality of processing modules, the end effector operable to transport the semiconductor substrate between the plurality of processing modules.
